(19) United States
(12) Patent Application Publication
(10) Pub. No.: US 2026/0150610 A1
(43) Pub. Date: May 28, 2026

(54) APPARATUS AND METHOD FOR CHEMICAL MECHANICAL POLISHING

(71) Applicant: Taiwan Semiconductor Manufacturing Company, Ltd., Hsinchu (TW)

(72) Inventors: Chin-Ming Kuo, Hsinchu City (TW); Te-Chien Hou, Hsinchu City (TW); Wen-Chih Chang, Hsinchu City (TW); Shich-Chang Suen, Hsinchu City (TW)

(73) Assignee: Taiwan Semiconductor Manufacturing Company, Ltd., Hsinchu (TW)

(21) Appl. No.: 18/962,360

(22) Filed: Nov. 27, 2024

(51) Int. Cl. H01L 21/306; B24B 57/02

(52) U.S. Cl. CPC H10P 52/402; B24B 57/02

(57) ABSTRACT

A chemical mechanical polishing (CMP) apparatus is provided. The CMP apparatus includes a platen and a wafer carrier disposed over the platen. The CMP apparatus further includes a slurry delivery system. The slurry delivery system includes a slurry conduit configured to dispense a slurry mixture onto the platen. The slurry delivery system further includes a light flow cell coupled to and circumferentially surrounding a segment of the slurry conduit, where the segment extends along a longitudinal axis. The light flow cell includes a light source configured to irradiate at least a portion of the segment.

### BACKGROUND

The semiconductor industry has experienced rapid growth due to improvements in the integration density of a variety of electronic components (e.g., transistors, diodes, resistors, capacitors, etc.). During the fabrication of semiconductor devices, such as integrated circuits, chemical mechanical polishing (CMP) processes are widely used. For example, as an integrated circuit is built layer by layer on a surface of a semiconductor wafer, CMP is used to planarize the topmost layer or layers to provide a level surface for subsequent fabrication operations. While apparatus and method associated with CMP are generally adequate, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of an example apparatus for chemical mechanical polishing (CMP), in accordance with some embodiments.

FIG. 2 illustrates a schematic view of an example slurry delivery system of the apparatus of FIG. 1, in accordance with some embodiments.

FIG. 3 illustrates a schematic view of an example slurry delivery system of the apparatus of FIG. 1, in accordance with some embodiments.

FIGS. 4, 5, 6, 7, 8 ,9, 10, and 11 each illustrate a schematic view of an example light flow cell of the slurry delivery system of FIG. 2 or FIG. 3, in accordance with some embodiments.

FIGS. 12A and 12B collectively illustrate a flow chart of an example method of using the apparatus of FIG. 1, in accordance with some embodiments.

FIG. 12C illustrates a flow chart of an example method of implementing an operation of the method of FIGS. 12A and 12B, in accordance with some embodiments.

FIGS. 13, 14, and 15 each illustrate schematic photoreactions implemented by an example light flow cell, in accordance with some embodiments.

FIGS. 16 and 18 each schematically illustrate an example multi-step CMP process, in accordance with some embodiments.

FIGS. 17 and 19 each schematically illustrate a relationship between removal rate and light efficiency of the example multi-step CMP process as illustrated in FIGS. 16 and 18, respectively, in accordance with some embodiments.

FIG. 20 schematically illustrates an example multi-step CMP process, in accordance with some embodiments.

FIG. 21 schematically illustrates an example multi-step CMP process, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A CMP process may be used at a number of time points during the fabrication of an integrated circuit. For example, the CMP process may be used to planarize the inter-level dielectric layers that separate the various circuit layers in an integrated circuit. The CMP process is also commonly used in the formation of the conductive lines of interconnect components in an integrated circuit. By abrasively polishing the surface of a semiconductor wafer, excess material and surface roughness in layers can be removed.

A CMP process is generally carried out by placing a semiconductor wafer in a wafer carrier that presses the wafer surface to be polished against a polishing pad attached to a platen. The platen and the wafer carrier are counter-rotated while a slurry mixture containing both an abrasive and reactive chemicals is applied to the polishing pad. The slurry mixture is transported to the wafer surface via the rotation of the polishing pad. The relative movement of the polishing pad and the wafer surface coupled with the reactive chemicals in the slurry mixture allows the CMP process to level the wafer surface by means of both physical and chemical actions.

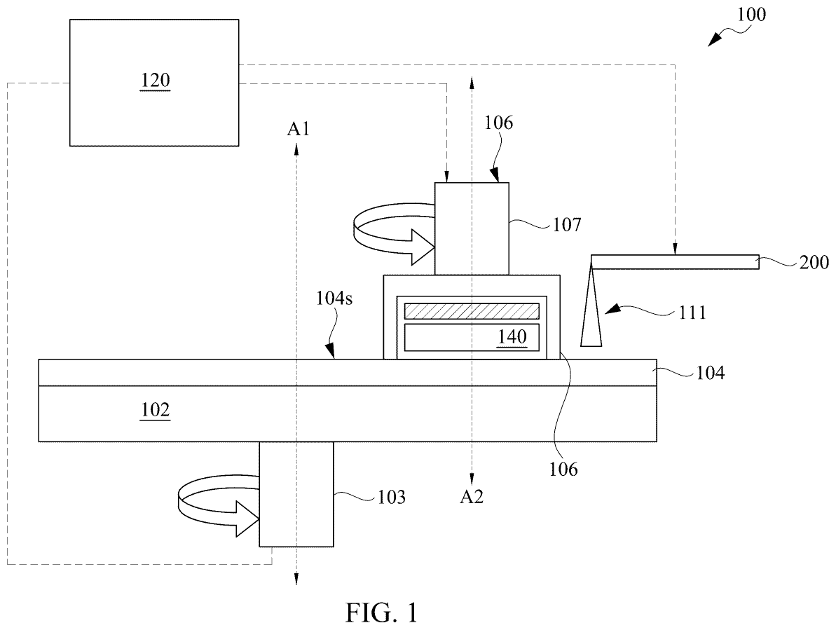

FIG. 1 schematically illustrates an apparatus 100 configured to implement a CMP process, according to some embodiments of the present disclosure. The apparatus 100 includes a platen 102, a polishing pad 104 provided on top of the platen 102, a wafer carrier 106 (alternatively referred to as a polishing head) configured to support a semiconductor wafer 140 (alternatively referred to as a workpiece), and a slurry delivery system 200 configured to dispense or deliver a slurry mixture 111 (alternatively referred to as a slurry or an abrasive slurry) to the polishing pad 104 to facilitate removal of materials from the semiconductor wafer 140 during a CMP process. The apparatus 100 further include a CMP control system 120 configured to control at least the platen 102, the wafer carrier 106, and the slurry delivery system 200. The apparatus 100 may include any additional components suitable for implementing CMP processes on the semiconductor wafer 140.

In some embodiments, the platen 102 is configured to rotate about an axis A1 in one or more directions (e.g., a clockwise direction and/or a counterclockwise direction). In some embodiments, the platen 102 is configured to be held stationary. In some embodiments, the platen 102 is configured to have a constant rotational speed. In alternative embodiments, the platen 102 is configured to have a variable rotational speed. The platen 102 can be rotated by a motor (not shown). In some embodiments, the motor can be an alternating current (AC) motor, a direct current (DC) motor, a universal motor, or another suitable motor. The platen 102 is configured to support the polishing pad 104, as shown in FIG. 1. In some embodiment, the platen 102 can be rotated by a rotating shaft 103, which have a variable rotational speed. The rotating shaft 103 can be rotated by a motor (not shown), which may include an AC motor, a DC motor, a universal motor, another suitable motor, or combinations thereof.

In some embodiments, the polishing pad 104 is coupled to the platen 102 such that the polishing pad 104 is rotated in a same direction and at a same speed as the platen 102. The polishing pad 104 includes a polishing surface 104s, such as a textured surface, which is configured to remove materials from the semiconductor wafer during a polishing operation.

The wafer carrier 106 is configured to support and retain the semiconductor wafer 140 proximate to the polishing surface 104s of the polishing pad 104 during the CMP process. In some embodiments, the wafer carrier 106 includes a retaining ring (not shown) to secure the semiconductor wafer 140. In some embodiments, the wafer carrier 106 includes a vacuum implement to secure the semiconductor wafer 140. The wafer carrier 106 is configured to rotate about an axis A2 in a direction that is the same as or different from a direction of rotation of the platen 102. In some embodiments, a spin shaft 107 rotates the wafer carrier 106 in a direction opposite to the direction of the rotation of the platen 102. In some embodiments, the spin shaft 107 is configured to have a constant rotational speed. In alternative embodiments, the spin shaft 107 is configured to have a variable rotational speed. The spin shaft 107 can be rotated by a motor (not shown), which may be similar to the motor for the rotating shaft 103 described herein.

The wafer carrier 106 may be moved in a direction perpendicular to the polishing surface 104s of the polishing pad 104. By moving the wafer carrier 106 in the direction perpendicular to the polishing surface 104s, a pressure is exerted on the semiconductor wafer 140 by the polishing pad 104. In some embodiments, such pressure, which is provided by a polishing force exerted on the semiconductor wafer 140, is adjustable by adjusting a position of the wafer carrier 106 relative to the polishing surface 104s. In order to remove any debris generated by the CMP process and maintain a desired polishing rate, the polishing pad 104 may be conditioned before, during, and/or after the CMP process using at least a conditioning disc (not shown), for example.

The slurry delivery system 200 is configured to dispense the slurry mixture 111 onto the polishing surface 104s of the polishing pad 104. Though not depicted in FIG. 1, the slurry delivery system 200 includes at least a slurry storage unit, a slurry conduit, a light flow cell, and a nozzle. The slurry storage unit is configured to store and contain the slurry mixture 111. The slurry conduit includes an inlet fluidly coupled to the slurry storage unit and an outlet fluidly coupled to the nozzle configured to dispense the slurry mixture 111 (onto the polishing pad 104, for example). The light flow cell is configured to impart a photoreaction to the slurry mixture 111 during the dispensing process, resulting in a chemical transformation of one or more component (e.g., an additive) of the slurry mixture 111. In some embodiments, the slurry delivery system 200 further includes a slurry mixing unit (not shown) fluidly coupled to the slurry conduit between the inlet and the outlet and configured to mix various components prior to delivering and dispensing the slurry mixture 111 onto the polishing surface 104s of the polishing pad 104. The slurry delivery system 200 may include additional components suitable for receiving, mixing, delivering, treating, and/or dispensing the slurry mixture 111. Details of the slurry delivery system 200 are described below.

The CMP control system 120 is communicatively coupled to various components of the apparatus 100 including at least the platen 102, the wafer carrier 106, and the slurry delivery system 200. In this regard, the CMP control system 120 is configured to command the various components of the apparatus 100 to implement the CMP process, a brief example of which is described in detail below.

As the semiconductor manufacturing process becomes increasingly complex, multi-film structures including sacrificial layers or protective layers, for example, are introduced for downstream fabrication processes, which may require the CMP process to break through different materials. In this regard, using a single slurry mixture to perform a CMP process on multi-film structures may result in mismatched material removal rates (RRs) between the different materials, thereby compromising uniformity of the polishing process. In this regard, existing CMP technologies generally rely on the application of slurry mixtures with different compositions and/or polishing pads with different textures to respectively and sequentially remove the different materials in the multi-film structures. While such an approach has been generally adequate in improving the uniformity of the CMP process, it has not been entirely satisfactory in all aspects.

The present disclosure provides embodiments in which a single slurry mixture, in combination with a single polishing pad, is utilized to achieve varying RRs for materials of different compositions in a multi-film structure during a multi-step CMP process. In the present embodiments, the multi-step CMP process is implemented using a slurry delivery system (e.g., the slurry delivery system 200) that includes at least a slurry conduit (e.g., slurry conduit 202) and a light flow cell (e.g., light flow cell 300) coupled to a segment of the slurry conduit through which the slurry mixture (e.g., the slurry mixture 111) is dispensed onto the platen (e.g., the platen 102). In some embodiments, the slurry mixture includes at least an abrasive (e.g., abrasive 152) and an additive (e.g., additive 156) configured to enhance or inhibit the removal (or polishing) of a given material. In various embodiments, the additive is chemically transformed, directly or indirectly, during a photoreaction initiated by the activation of the light flow cell, resulting in a processed slurry mixture that is subsequently dispensed onto the polishing pad. By altering one or more parameters of the photoreaction, the additive may undergo different states of chemical transformation, thereby independently tuning the CMP process to achieve varying RRs of the different materials without requiring different slurry mixtures and/or different polishing pads. In some instances, by tuning the parameters of the photoreaction, the RRs of different materials may be made to be substantially the same to achieve polishing uniformity across a polishing surface. In other instances, by tuning the parameters of the photoreaction, the RRs of different materials may be intentionally adjusted to be different to achieve a desired polishing profile. Advantageously, complexity of the CMP process for planarizing a multi-film structure may be reduced to improve the overall throughput of the polishing process without significantly impacting the uniformity thereof.

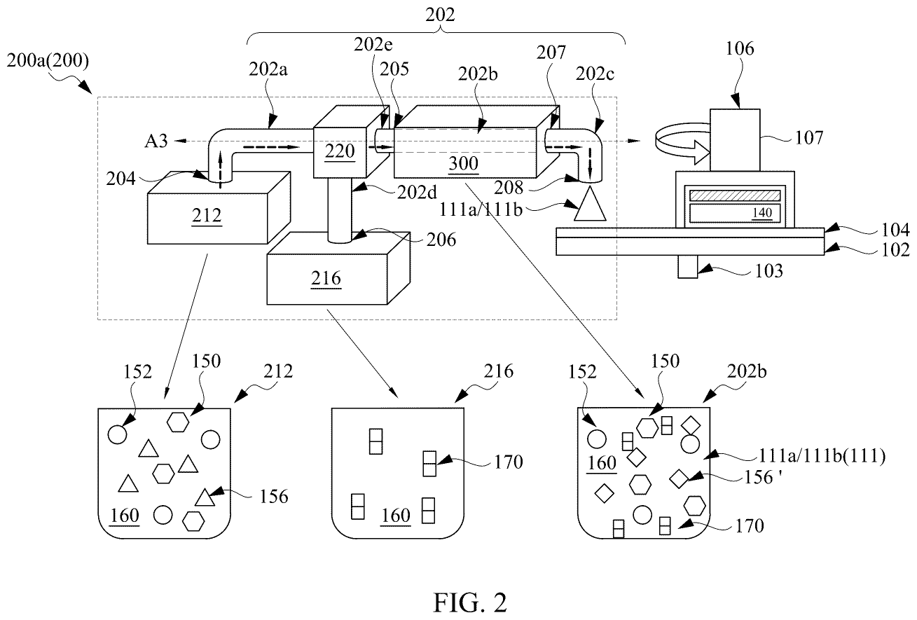

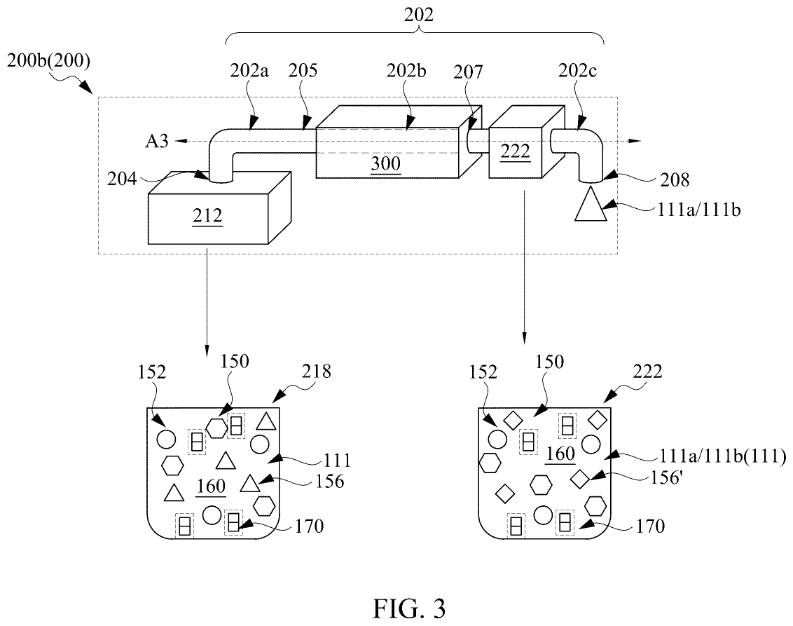

FIGS. 2 and 3 schematically illustrate slurry delivery systems 200a and 200b (hereafter referred to as systems 200a and 200b), respectively. Each of the systems 200a and 200b represents an embodiment of the slurry delivery system 200 as a component of the apparatus 100 of FIG. 1, according to some embodiments of the present disclosure. It should be understood that, for purposes of brevity, the same elements in FIGS. 2 and 3 are referenced to using the same numerals and repetitive details may be omitted or otherwise simplified.

Referring to FIG. 2, the system 200a includes a slurry conduit 202 (alternatively referred to as a slurry arm or a slurry tube) through which the slurry mixture 111 is delivered and dispensed. The slurry conduit 202 includes an inlet 204 disposed at a first end of the slurry conduit 202 and an outlet 208 disposed at a second end of the slurry conduit 202 opposite to the first end. The system 200a includes a slurry storage unit 212 coupled to and in fluid communication with the inlet 204, where the slurry storage unit 212 is configured to receive and store one or more of the various components of the slurry mixture 111. In some embodiments, the system 200a includes a mechanical pump operatively coupled to the slurry storage unit 212 and configured to actively pump the various components of the slurry mixture 111 through the slurry conduit 202.

In some embodiments, the system 200a optionally includes a mixer 220 in fluid communication with the slurry storage unit 212. The mixer 220 is coupled to the slurry storage unit 212 through a segment 202a of the slurry conduit 202, where the segment 202a terminates at the inlet 204. In some embodiments, the mixer 220 includes a mechanical device, such as a blender, configured to mix the components of the slurry mixture 111 stored in, and subsequently delivered from, the slurry storage unit 212 with additional components, such as a photosensitive reactor (e.g., photosensitive reactor 170). Such additional components may be stored in and received from a reactor storage unit 216. The reactor storage unit 216 is coupled to and in fluid communication with the mixer 220 through a segment 202d of the slurry conduit 202, where the segment 202d terminates at an inlet 206. In this regard, the embodiment of the slurry conduit 202 depicted in FIG. 200a includes two inlets, the inlet 204 and the inlet 206, through which the various components of the slurry mixture 111 are received and subsequently delivered through the remainder segments of the slurry conduit 202. In some embodiments, as described in detail below, the mixer 220 and the reactor storage unit 216 are omitted from the slurry delivery system.

The system 200a further includes a light flow cell 300 coupled to a segment 202b of the slurry conduit 202. In some embodiments, the light flow cell 300 circumferentially surrounds an outer surface of the segment 202b, which extends lengthwise along a longitudinal axis A3 between the mixer 220 and the outlet 208. In other words, the segment 202b receives the slurry mixture 111 that has been processed (e.g., mixed) by the mixer 220. The segment 202b includes an inlet 205 and an outlet 207 opposite to the inlet 205. In addition, a segment 202c of the slurry conduit 202 is coupled to and in fluid communication with the outlet 207 of the segment 202b, such that the segment 202c extends between the light flow cell 300 and the outlet 208. Further still, a segment 202e of the slurry conduit 202 is coupled to and in fluid communication with the inlet 205 of the segment 202b, such that the segment 202e extends between the light flow cell and the mixer 220 (if included). In the present embodiments, the slurry mixture 111 passing through the segment 202b (i.e., between the inlet 105 and the outlet 207) undergoes at least one photoreaction implemented by the light flow cell 300. In this regard, the segment 202b includes a segment body configured to be optically transparent to the light source of the light flow cell 300. Details of the structure of the light flow cell 300 are described below.

In some embodiments, referring to FIG. 2 and an enlarged depiction of a content of the slurry storage unit 212, the various components of the slurry mixture 111 stored in the slurry storage unit 212 includes at least a reactant 150, an abrasive 152, an additive 156, and a solvent 160. The reactant 150 may be a chemical, such as an oxidizer or a hydrolyzer, which chemically reacts with a material disposed on a workpiece (e.g., the semiconductor wafer 140) in order to assist the polishing process using the polishing pad 104. For embodiments in which the material to be removed includes a metal, such as tungsten (W), the reactant 150 may include, for example, hydrogen peroxide, Cr₂O₇, MnO₄, OsO₄, other suitable reactants, or combinations thereof. For embodiments in which a material to be removed includes a dielectric material, such as an oxide (e.g., silicon oxide), the reactant 150 may include nitric acid (HNO₃), potassium hydroxide (KOH), ammonium hydroxide (NH₄OH), other suitable reactants, or combinations thereof.

The abrasive 152 may include any suitable particles that, in conjunction with the mechanical movement of the polishing pad 104 relative to the wafer carrier 106 (i.e., the semiconductor wafer 140), is configured to remove portions of the material (having undergone chemical reaction(s) with the reactant) during the CMP process. In some embodiments, the abrasive 152 includes silicon oxide, aluminum oxide, cerium oxide, polycrystalline diamond, polymer particles (e.g., polymethacrylate, or the like), other suitable reactants, or combinations thereof. In some embodiments, the abrasive 152 includes colloids having a composition described above. In some embodiments, the abrasive 152 is photosensitive and is thus capable of undergoing chemical change when exposed to light during a photoreaction implemented by the light flow cell 300.

The solvent 160 may be utilized to combine the reactant 150, the abrasive 152, and any other components including, for example, a surfactant, a corrosion inhibitor, a chelating agent, a pH adjustor, other suitable components, or combinations thereof. In some embodiments, the solvent 160 allows the slurry mixture to be moved and dispersed onto the polishing pad 104. In some embodiments, the solvent 160 includes deionized water (DIW), alcohol, an azeotropic mixture thereof, other suitable components, or combinations thereof. Any additional components which may be useful to the polishing process may be utilized, and all such additives are fully intended to be included within the scope of the embodiments.

The additive 156 may include one or more agent configured to influence aspects of the polishing process by altering the RR of a material provided on a workpiece. In some embodiments, the additive 156 includes a polishing enhancer (hereafter referred to as an enhancer) that, in its active state, can render a surface portion of the material to be more susceptible to the chemical and/or mechanical effect imparted by the components of the slurry mixture 111, e.g., the reactant 150 and/or the abrasive 152, thereby increasing the RR of the material during the CMP process. On the contrary, the enhancer, in its inactive state, can render the surface portion of the material to withstand the chemical and/or mechanical effect imparted by the components of the slurry mixture 111 during the CMP process, thereby decreasing the RR of the material.

In some embodiments, the additive 156 includes a polishing inhibitor (hereafter referred to as an inhibitor) that, in its active state, can form a protective layer (e.g., a polymer layer) over a surface portion of a material provided on a workpiece, thereby reducing the RR of such material during the CMP process. On the contrary, the inhibitor, in its inactive state, does not form the protective layer, thereby rendering the surface portion of the same material to be more susceptible to the chemical and/or mechanical effect imparted by the components of the slurry mixture 111 during the CMP process. In this regard, the polishing inhibitor in an inactive state can increase the RR of the material in a manner similar to the that of the enhancer in its active state.

In some embodiments, the additive 156 includes an enhancer, an inhibitor, or both. In furtherance to such embodiments, the state (active or inactive) of each of the enhancer and the inhibitor can be changed independently by adjusting one or more parameters of the photoreaction implemented by the light flow cell 300. In some embodiments, the enhancer and the inhibitor are respectively considered a component of a photosensitive agent PA in the slurry mixture 111 and are therefore each capable of being transformed to an active state or an inactive state directly by the photoreaction implemented by the light flow cell 300. For example, referring to FIG. 2 and an enlarged depiction of a content of the segment 202b, the additive 156 becomes a processed additive 156′ (alternatively referred to as a treated additive) after undergoing the photoreaction implemented by the light flow cell 300, where the processed additive 156′ may include the enhancer in an active state or an inactive state, and/or an inhibitor in an active state or an inactive state. Accordingly, the slurry mixture 111 may be considered a processed slurry mixture 111a/111b, as described in detail below.

In some embodiments, the enhancer and the inhibitor are not components of the photosensitive agent PA (i.e., do not respond to light irradiated by the light flow cell 300) and can therefore only be transformed to an active state or an inactive state by an intermediate agent, such as a photosensitive reactor 170, through the photoreaction implemented by the light flow cell 300. In this regard, the photosensitive reactor 170 is considered a component of the photosensitive agent PA in the slurry mixture 111. In some embodiments, referring to FIG. 2 and an enlarged depiction of a content of the reactor storage unit 216, the photosensitive reactor 170 is mixed with the solvent 160, stored in the reactor storage unit 216, and subsequently mixed with other components of the slurry mixture 111 (previously stored in the slurry storage unit 212) in the mixer 220.

Referring to FIG. 3, the system 200b is similar to the system 200a with the exception that the system 200b does not include a reactor storage unit 216 or the mixer 220. In some embodiments, referring to an enlarged depiction of the content of the slurry storage unit 212, in addition to the same components (e.g., the reactant 150, the abrasive 152, the additive 156, and the solvent 160) described above with respect to the system 200a, the slurry mixture 111 stored in the slurry storage unit 212 further includes the photosensitive reactor 170 mixed therein. As the slurry storage unit 212 includes such a prepared mixture, the use of the mixer 220 is obviated. For embodiments in which the enhancer and/or the inhibitor are components of the photosensitive agent PA, the photosensitive reactor 170 is omitted from the content of the slurry mixture 111.

Furthermore, the system 200b may include a mixer 222 coupled between the light flow cell 300 and the outlet 208 of the slurry conduit 202. In this regard, referring to an enlarged depiction of the content of the mixer 222, the mixer 222 is configured to receive the slurry mixture 111 (i.e., the processed slurry mixture 111a/111b) after it has undergone the photoreaction in the light flow cell 300 and subsequently disperse the processed additive 156′ throughout the slurry mixture 111 (i.e., the processed slurry mixture 111a/111b) before dispensing the slurry mixture 111 over the polishing pad 104. The mixer 222 may have substantially the same structure as the mixer 220 and may include at least a blender, for example. In some embodiments, the mixer 222 is omitted from the system 200b such that the segment 202c extends continuously between the outlet 207 of the light flow cell 300 and the outlet 208 of the slurry conduit 202.

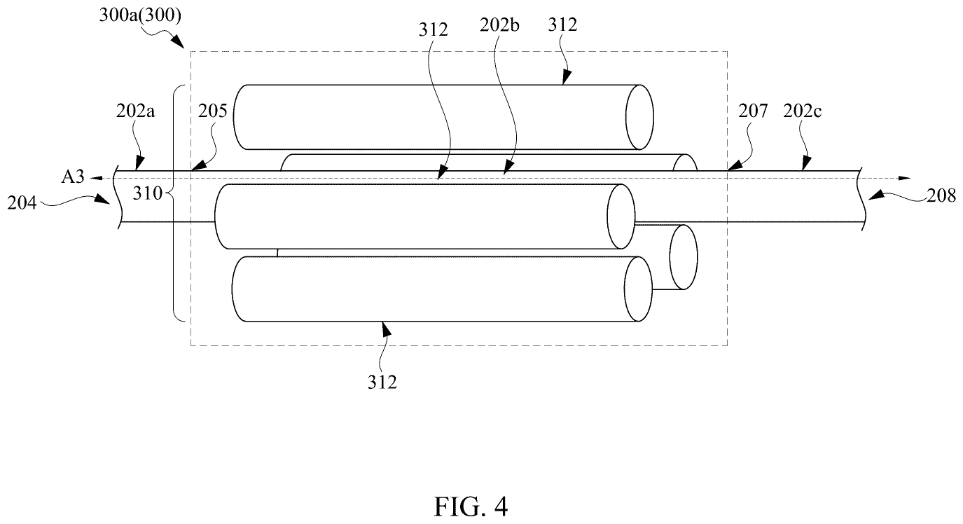

FIGS. 4-11 schematically illustrate the light flow cells 300a, 300b, 300c, 300d, 300e, 300f, 300g, and 300h, respectively (hereafter referred to as cells 300a-300h). Each of the cells 300a-300h represents an embodiment the light flow cell 300 as a component of the slurry delivery system 200 described herein, according to some embodiments of the present disclosure. It should be understood that, for purposes of brevity, the same elements in FIGS. 4-11 are referenced to using the same numerals and repetitive details may be omitted or otherwise simplified.

Referring to FIG. 4, the cell 300a includes an array 310 of a plurality of light holders 312. In some embodiments, the light holders 312 are each configured as a cylinder extending lengthwise (e.g., elongating) along the longitudinal axis A3. In some embodiments, the light holders 312 are spatially arranged to circumferentially surround the segment 202b, thereby maximizing coverage of the segment 202b by the light holders 312. In one such example, the segment 202b extends parallel and adjacent to at least sone of the light holders 312 along the longitudinal axis A3. In another such example, the segment 202b extends through a center space of the array 310 as depicted in FIG. 4. In the depicted embodiment, the segment 202b is configured as a substantially elongated, straight segment of the slurry conduit 202.

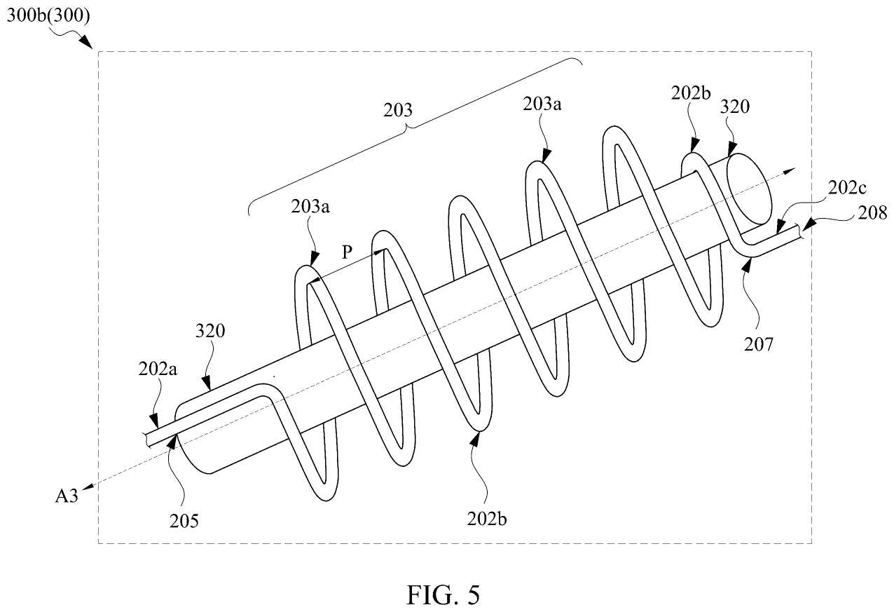

Referring to FIG. 5, the cell 300b includes a single light holder 320, rather than an array of light holders. In some embodiments, the light holder 320 is configured as a cylinder extending lengthwise (e.g., elongating) along the longitudinal axis A3, similar to each of the light holder 312. However, different from the cell 300a, the segment 202b is arranged in a helical pattern 203 surrounding an outer surface of the light holder 320. In some embodiments, the helical pattern 203 includes a plurality of loops 203a spaced apart by a pitch P along the longitudinal axis A3.

Although the light holder 312 and the light holder 320 are each depicted to have a cylindrical shape, the embodiments of the cell 300a and the cell 300b, respectively, are not limited to such configuration. For example, the light holder 312 and the light holder 320 may each be configured to have other shapes such as rectangular or the like. In some embodiments, the light holder 312 and the light holder 320 are each configured to have an elongated shape having a length similar to or the same as a length of the segment 202b (i.e., the length extending between the inlet 205 and the outlet 207) to maximize an extent of exposure of the slurry mixture 111 to the photoreaction implemented by the cell 300a and the cell 300b, respectively.

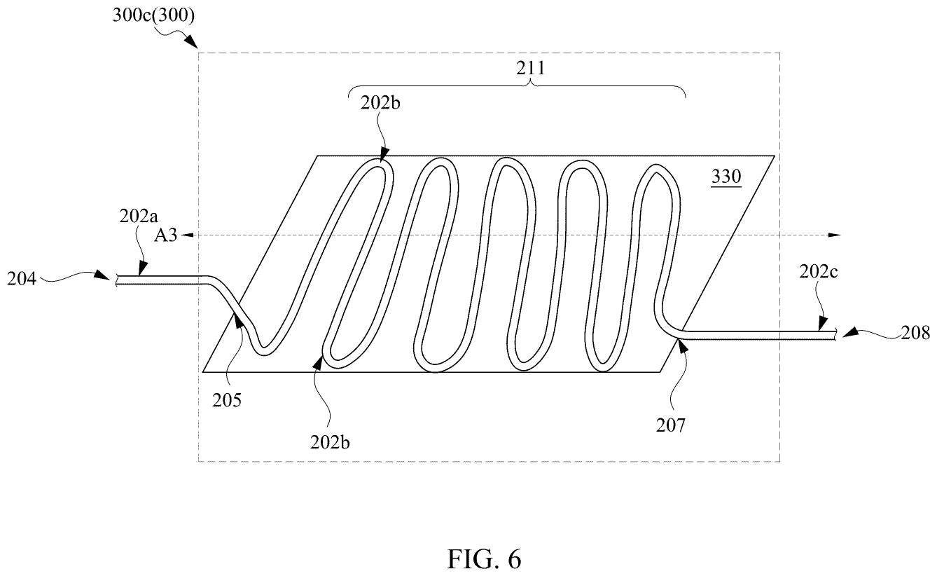

Referring to FIG. 6, the cell 300c includes a single light holder 330 similar to the cell 300b. However, different from the cells 300a and 300b, the light holder 330 is configured as a sheet that extends in a plane parallel to the longitudinal axis A3. As such, the segment 202b is arranged in a serpentine pattern 211 across a surface of the light holder 330. Such an arrangement allows the exposure of the slurry mixture 111 flowing through the segment 202b to be maximized across the light holder 330 (and the light source supported thereby).

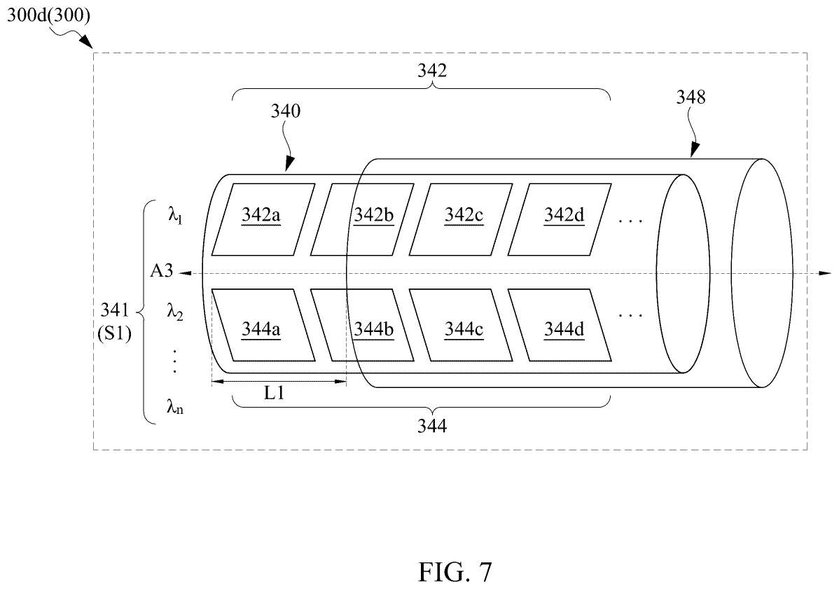

Various embodiments of the light flow cell 300, e.g., the cells 300a-300h, each include a light source positionally supported by the light holders (e.g., the light holders 312, 320, and 330), where the light source is configured to irradiate at least a portion of the segment 202b (i.e., the slurry mixture 111 passing through the segment 202b). Example embodiments of the types and/or arrangements of the light source with respect to the light holders are described in detail below in reference to the cells 300d-300h of FIGS. 7-11.

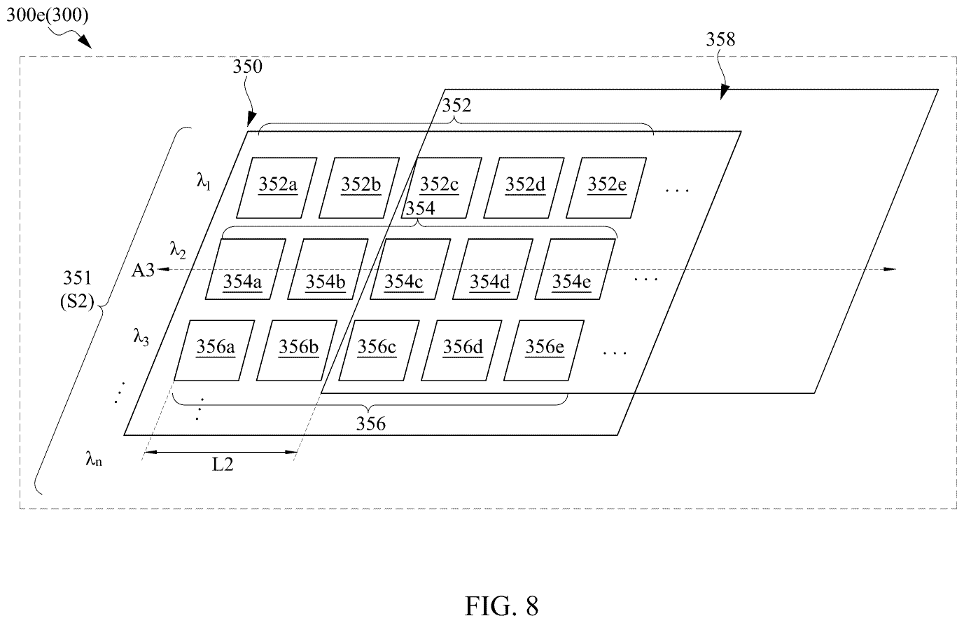

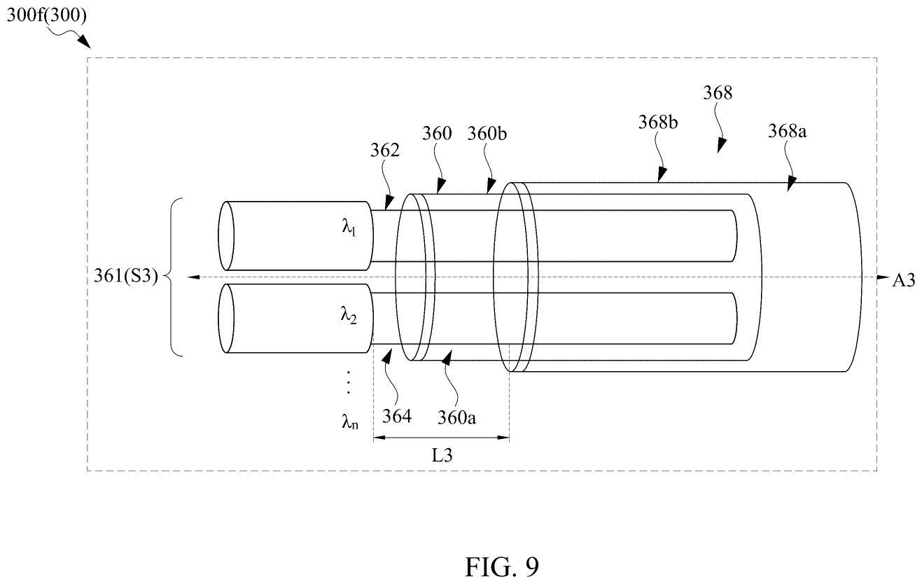

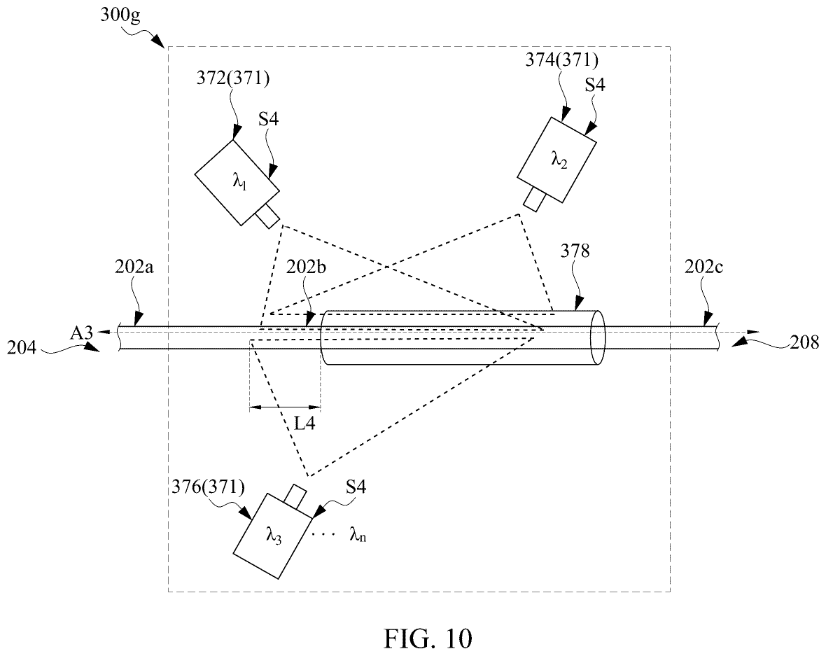

In some embodiments, referring to FIGS. 7 and 8 collectively, the light source may include a plurality of light-emitting diodes (LEDs) arranged in an array. For example, referring to FIG. 7, the cell 300d includes a light source S1 comprising an array 341 of LEDs (alternatively referred to as an array of light elements) disposed on an outer surface of a light holder 340. In some embodiments, the light holder 340 is configured to have a cylindrical shape similar to that of the light holders 312 and 320 described herein. In some embodiments, the array 341 includes at least a first row 342 of LEDs (e.g., LEDs 342a, 342b, 342c, 342d, etc.) and a second row 344 of LEDs (e.g., LEDs 344a, 344b, 344c, 344d, etc.) disposed on an outer surface of the light holder 340, where the first row 342 and the second row 344 are spaced apart circumferentially along the outer surface of the light holder 340. In some embodiments, the LEDs 342a-342d are configured to irradiate (or emit) light in a first wavelength (λ₁) and the LEDs 344a-344d are configured to irradiate light in a second wavelength (λ₂) that is different from the first wavelength. The cell 300d may include additional rows of LEDs configured to irradiate light in different wavelengths (λ₃, λ₄, . . . λₙ). These wavelengths may be in the visible light spectrum, e.g., light having a wavelength between about 380 nm to about 750 nm, the IR spectrum, e.g., light having a wavelength between about 700 nm and about 50 μm, the UV spectrum, e.g., light having a wavelength between about 100 nm and 400 nm, or other suitable spectra. In this regard, the light source S1 may alternatively be referred to as a multi-wavelength light source S1. In some embodiments, though not depicted herein, the segment 202b may be arranged in a helical pattern, similar to the helical pattern 203 depicted in FIG. 5, that surrounds the outer surface of the light holder 340.

Furthermore, the cell 300d may include a light mask 348 positioned over the light source S1 and under the segment 202b. In other words, the light mask 348 is disposed between the light source S1, which is supported on the light holder 340, and the segment 202b. The light mask 348 is configured to be removably positioned (e.g., slidable) over the light source S1 along the longitudinal axis A3 so as to adjust an extent of exposure of the slurry mixture 111 in the segment 202b to the light source S1. For example, by sliding the light mask 348 along the longitudinal axis A3, an irradiation length L1 can be adjusted to change the extent of exposure (alternatively referred to as an area of exposure or an area of illumination) of the slurry mixture 111 to the light source S1. In some embodiments, the light mask 348 is omitted from the cell 300d.

Similarly, referring to FIG. 8, the cell 300e includes a light source S2 comprising an array 351 of LEDs (alternatively referred to as an array of light elements) disposed on an outer surface of a light holder 350. In some embodiments, the light holder 350 is as a sheet that extends in a plane parallel to the longitudinal axis A3 similar to that of the light holder 330 described herein. In some embodiments, the array 351 includes at least a first row 352 of LEDs (e.g., LEDs 352a, 352b, 352c, 352d, etc.), a second row 354 of LEDs (e.g., LEDs 354a, 354b, 354c, 354d, etc.), and a third row 356 (e.g., LEDs 356a, 356b, 356c, and 356d, etc.) disposed on a surface of the light holder 350, where the first row 352, the second row 354, and the third row 356 are spaced apart along a direction perpendicular to the longitudinal axis A3. In some embodiments, the LEDs 352a-352d are configured to irradiate (or emit) light in a first wavelength (λ₁), the LEDs 354a-354d are configured to irradiate light in a second wavelength (λ₂) that is different from the first wavelength, and the LEDs 356a-356d are configured to irradiate light in a third wavelength (λ₃) that is different from the first wavelength and the second wavelength. The cell 300e may include additional rows of LEDs configured to irradiate light in different wavelengths (λ₄, λ₅, . . . λₙ), such as in the visible light spectrum, the IR spectrum, or the UV spectrum, as described above. In this regard, the light source S2 may alternatively be referred to as a multi-wavelength light source S2. In some embodiments, though not depicted herein, the segment 202b may be arranged in a serpentine pattern, similar to the serpentine pattern 211 depicted in FIG. 6, that extends over the surface of the light holder 350.

Additionally, the cell 300e may include a light mask 358 positioned over the light source S2 and under the segment 202b, i.e., the light mask 358 is disposed between the light source S2, which is supported on the light holder 350, and the segment 202b. The light mask 358 has a function similar to that of the light mask 348. For example, an extent of exposure of the light source S2 may be adjusted by changing an irradiation length L2 along the longitudinal axis A3. In some embodiments, the light mask 358 is omitted from the cell 300e.

In some embodiments, the light source may include a plurality of lamps. For example, referring to FIG. 9, the cell 300f may include a light source S3 disposed within a light holder 360, where the light source S3 includes an array 361 of a first lamp 362 and a second lamp 364 (alternatively referred to as an array of light elements) extending parallel to one another. The light holder 360 is configured as a tube having a lumen 360a defined by a tube body 360b. In some embodiments, the first lamp 362 and the second lamp 364 extends through the lumen 360a along the longitudinal axis A3.

The first lamp 362 and the second lamp 364 may each be configured to irradiate light in any ranges of wavelengths suitable for inducing the photoreaction in the slurry mixture 111 passing through the segment 202b. For example, the first lamp 362 and the second lamp 364 may each be configured to irradiate light in the visible light spectrum, the IR spectrum, the UV spectrum, or other suitable spectra, as described above. In some embodiments, the first lamp 362 is configured to irradiate light in a first wavelength (λ₁), and the second lamp 364 is configured to irradiate light in a third wavelength (λ₂) that is different from the first wavelength. The cell 300f may include additional lamps configured to irradiate light in different wavelengths (λ₃, λ₄, . . . λₙ). In this regard, the light source S3 may alternatively be referred to as a multi-wavelength light source S3. It is noted that although the first lamp 362 and the second lamp 364 are each depicted to have a cylindrical shape, embodiments of the present disclosure are also applicable to other configurations.

In some embodiments, though not depicted herein, the segment 202b may be arranged in a helical pattern, similar to the helical pattern 203 depicted in FIG. 5, that surrounds the outer surface of the light holder 360. Additionally, the cell 300f may include a light mask 368 positioned over the light source S3 and under the segment 202b, i.e., the light mask 358 is disposed between the light source S3 and the segment 202b. The light mask 368 is configured as a tube having a lumen 368a defined by a tube body 368b. In some embodiments, the light holder 360 extends through the lumen 368a along the longitudinal axis A3. The light mask 368 has a function similar to that of the light mask 348. For example, an extent of exposure of the light source S3 may be adjusted by changing an irradiation length L3 along the longitudinal axis A3. In some embodiments, the light mask 368 is omitted from the cell 300f.

In some embodiments, referring to FIGS. 10 and 11 collectively, the light source may include a plurality of lasers arranged in an array. For example, referring to FIG. 10, the cell 300g includes a light source S4 comprising an array 371 of a first laser 372, a second laser 374, and a third laser 376 (alternatively referred to as an array of light elements) configured to illuminate (or irradiate) at least portions of the segment 202b. In the depicted embodiment, the segment 202b is configured as a substantially elongated, straight segment of the slurry conduit 202, similar to the configuration of the segment 202b in the cell 300a.

Furthermore, in the depicted embodiment, the cell 300g does not include any light holder. In this regard, positions of the lasers in the array 371 can be determined with flexibility based on factors such as a number of the lasers included in the light source S4, an area of illumination, a size of the cell 300g, and/or the like. In some embodiments, the segment 202b is exposed to the illumination of the lasers 372-376 in the array 371, which are positioned over and separated from the segment 202b. In some embodiments, the lasers in the array 371are positioned to surround the segment 202b from multiple directions (e.g., above, below, etc.).

The laser 372-376 may each be configured to irradiate light in any ranges of wavelengths, such as in the visible light spectrum, the IR spectrum, or the UV spectrum, as described above, to be suitable for inducing the photoreaction in the slurry mixture 111 passing through the segment 202b. In some embodiments, the first laser 372 is configured to irradiate light in a first wavelength (λ₁), the second laser 374 is configured to irradiate light in a third wavelength (λ₂) that is different from the first wavelength, and the third laser 376 is configured to irradiate light in a third wavelength (λ₂) that is different from the first wavelength and the second wavelength. The cell 300g may include additional lasers configured to irradiate light in different wavelengths (λ₄, λ₅, . . . λₙ). In this regard, the light source S4 may alternatively be referred to as a multi-wavelength light source S4.

In some embodiments, the cell 300b further includes a light mask 378 positioned over the segment 202b and under the light source S4, i.e., the light mask 378 is disposed between the light source S4 and the segment 202b. The light mask 378 has a function similar to that of the light mask 348. For example, an extent of exposure of the light source S4 may be adjusted by changing an irradiation length L4 along the longitudinal axis A3. In some embodiments, the light mask 378 is omitted from the cell 300g.

In some embodiments, referring to FIG. 11, the cell 300h includes a light source S5 comprising an array 381 of a first laser 382, a second laser 384, and a third laser 386 (alternatively referred to as an array of light elements) configured to illuminate at least portions of the segment 202b. The lasers 382-386 may be substantially similar to or the same as the lasers 372-376 and their descriptions are therefore omitted herein for purposes of brevity. The light source S5 may alternatively be referred to as a multi-wavelength light source S5.

The cell 300h further includes a light holder 380 configured as a sheet that extends in a plane parallel to the longitudinal axis A3, similar to the light holder 330 in the cell 300c. Accordingly, the segment 202b is arranged in a serpentine pattern 213 across a surface of the light holder 380. In the depicted embodiment, the segment 202b is positioned (e.g., physically supported) on the light holder 380 and exposed to the illumination of the lasers in the array 381, which may be spatially arranged over and above the segment 202b. In some embodiments, the lasers within the array 381 may be spatially offset to optimize the area of exposure provided by each of the lasers 382-386.

In some embodiments, the cell 300h further includes a light mask 388 positioned over the segment 202b and under the light source S5, i.e., the light mask 388 is disposed between the light source S5 and the segment 202b. The light mask 388 has a function similar to that of the light mask 348. For example, an extent of exposure of the light source S4 may be adjusted by changing an irradiation length L5 along the longitudinal axis A3. In some embodiments, the light mask 388 is omitted from the cell 300h.

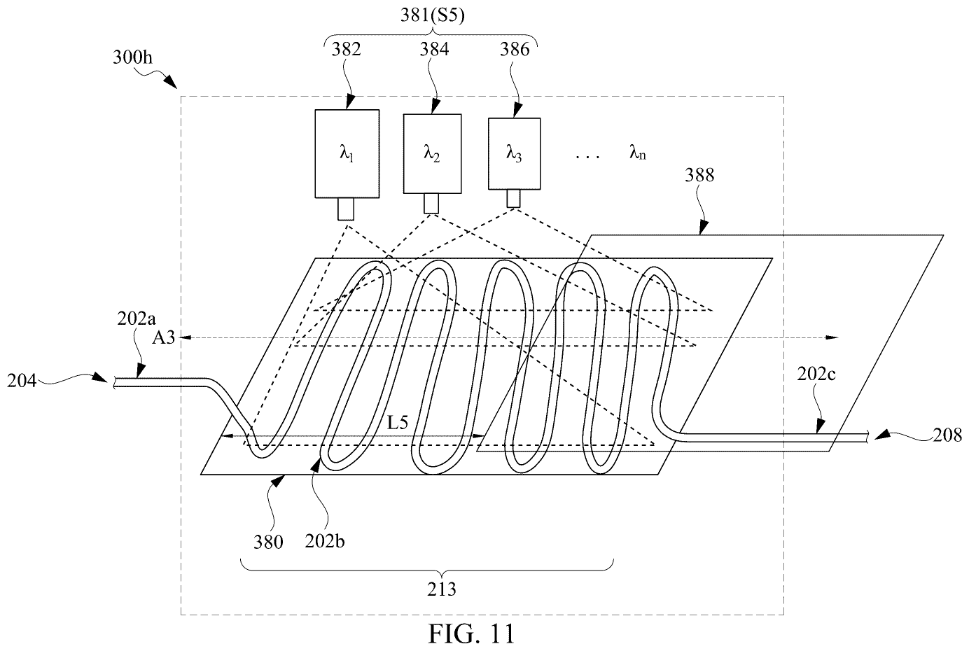

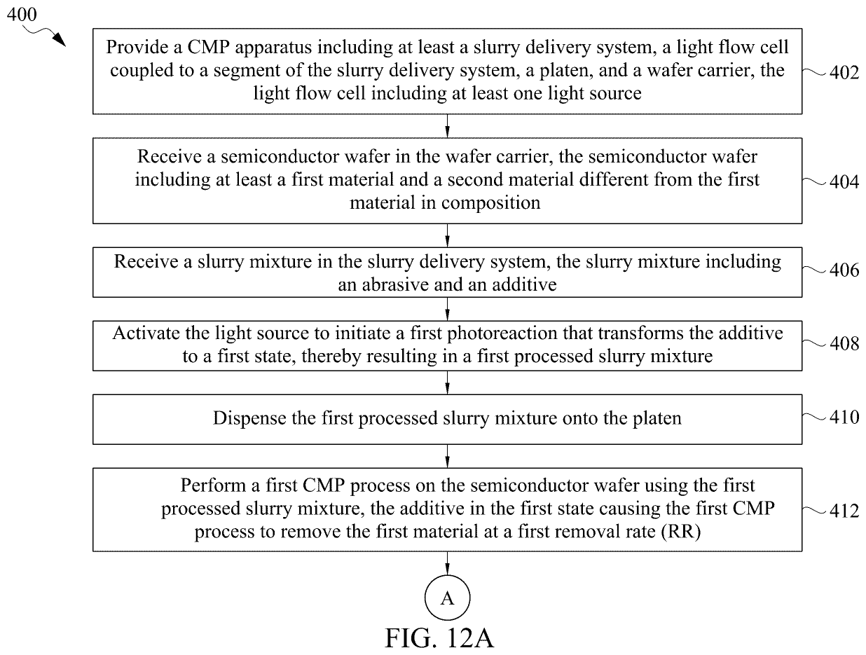

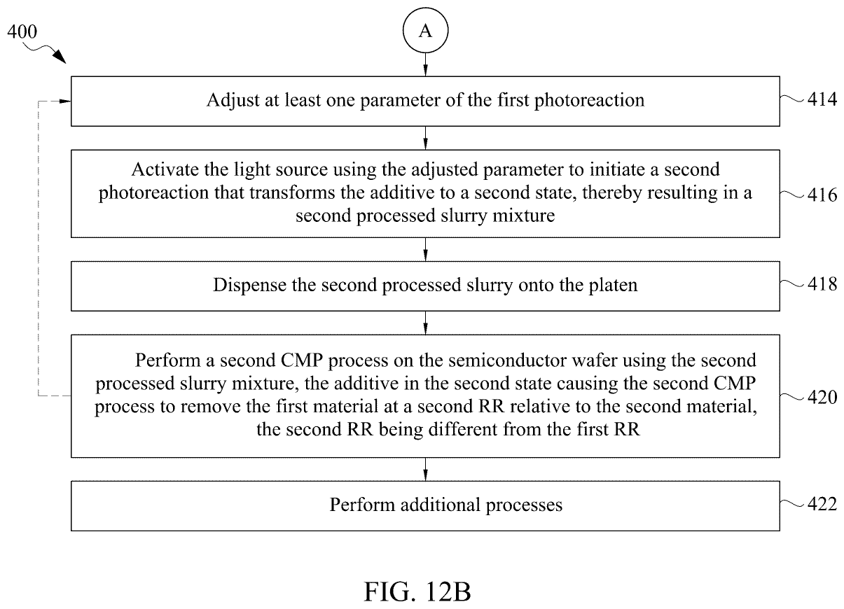

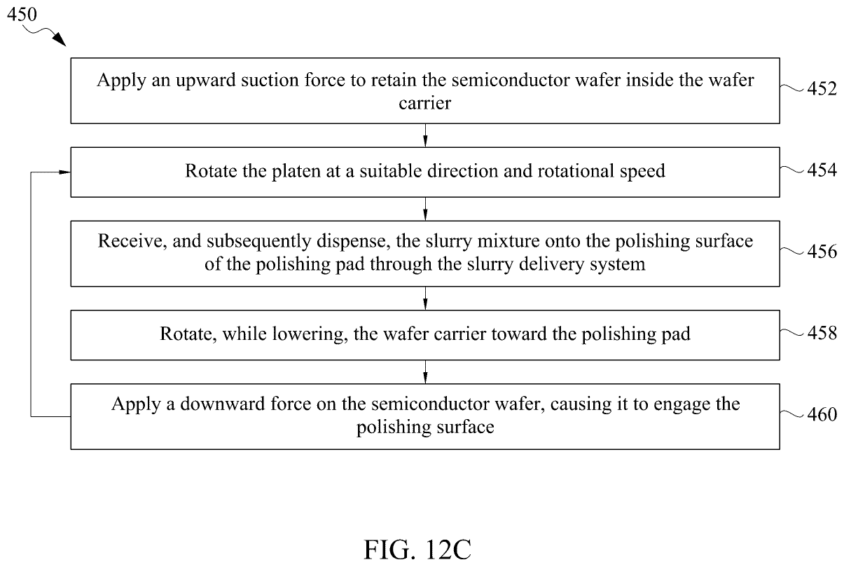

FIGS. 12A and 12B collectively illustrate a flow chart of an example method 400 for using an embodiment of a CMP apparatus, e.g., the apparatus 100 described herein, in accordance with some embodiments. It should be noted that the method 400 is merely an example and is not intended to limit the present disclosure. Accordingly, it is understood that additional steps/operations may be provided before, during, and after the method 400 of FIGS. 12A and 12B, and that some other operations may only be briefly described herein. In some embodiments, an operation of the method 400 is implemented by an example method 450, which is illustrated as a flow chart in FIG. 12C. Operations of the method 400 and the method 450 may be associated with depictions of the apparatus 100, and portions thereof, as shown in FIGS. 1-11.

Referring to FIGS. 1-11, for example, the method 400 begins at operation 402 during which a CMP apparatus, e.g., the apparatus 100, is provided. The apparatus 100 includes at least the slurry delivery system 200 (e.g., the systems 200a and 200b) and the light flow cell 300 (e.g., the cells 300a-300h) coupled to the segment 202b of the slurry conduit 202 of the slurry delivery system 200. In some embodiments, the light flow cell 300 includes at least one light source (e.g., the light sources S1-S5) described herein. The apparatus 100 further includes the platen 102 configured to support the polishing pad 104 and the wafer carrier 106 configured to receive and retain the semiconductor wafer 140 (or the workpiece).

Referring to FIGS. 1 and 2, for example, the method 400 proceeds to operation 404 during which the semiconductor wafer 140 is received in (or provided to) the wafer carrier 106. In some embodiments, the semiconductor wafer 140 includes at least a first material and a second material disposed thereon. In various embodiments, the first material and the second material include different compositions, and respective top surfaces of the first material and the second material are horizontally uneven (or non-planar). In various embodiments, the first material and the second material exhibit different RRs when being polished using the same slurry mixture 111. The first material and the second material may each include one or more of silicon oxide (SiO₂), silicon nitride (Si₃N₄), polycrystalline silicon (poly-Si), tungsten (W), cobalt (Co), copper (Cu), tantalum (Ta), tantalum nitride (TaN), titanium (Ti), titanium nitride (TiN), molybdenum (Mo), ruthenium (Ru), other suitable materials, or combinations thereof. It is understood that the semiconductor wafer 140 may include additional material(s) disposed thereon.

Referring to FIGS. 2 and 3, for example, the method 400 proceeds to operation 406 during which the slurry mixture 111 is received in the slurry delivery system 200. In some embodiments, the slurry mixture 111 includes at least the abrasive 152 and the additive 156.

As described herein, the additive 156 may include the enhancer, the inhibitor, or both. In some embodiments, the enhancer and/or the inhibitor are components of the photosensitive agent PA capable of being transformed by the photoreaction implemented in the light flow cell 300. Additionally or alternatively, the abrasive 152 is a component of the photosensitive agent PA capable of being transformed by the photoreaction implemented in the light flow cell 300. In some embodiments, still referring to FIGS. 2 and 3, the enhancer and/or the inhibitor are not components of the photosensitive agent PA, and the slurry mixture 111 further includes the photosensitive reactor 170 as an intermediate agent configured to induce transformation of the enhancer and/or the inhibitor after being activated by the photoreaction first.

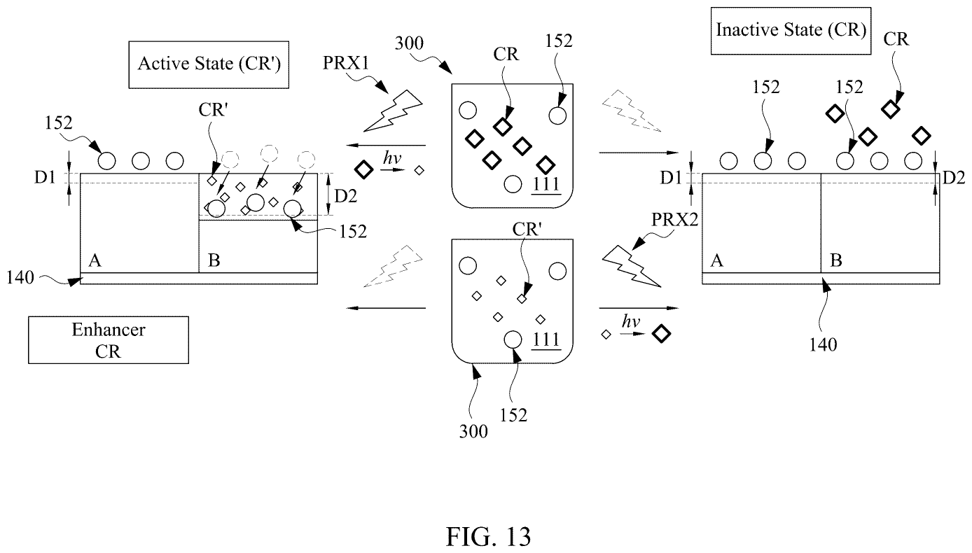

Referring to FIGS. 2, 3, 7-11, and 13-15, for example, the method 400 proceeds to operation 408 during which the light source S1-S5 in the light flow cell 300 is activated to initiate a first photoreaction that transforms the additive 156 to a first state (i.e., the processed additive 156′ described above), thereby resulting in a first processed slurry mixture 111a. In some embodiments, the first photoreaction alternatively or additionally transforms the abrasive 152 to the first state, thereby resulting in the first processed slurry mixture 111a. Example transformations of the additive 156 and the abrasive 152 are schematically illustrated in FIGS. 13-15 and described in detail below.

FIG. 13 illustrates a first photoreaction PRX1 that transforms the enhancer (i.e., the additive 156) from an inactive state CR to an active state CR′ (i.e., the first state). In the active state CR′, the enhancer causes the abrasive 152 in the first processed slurry mixture 111a to penetrate material B (i.e., a first material) at a first depth D1 and material A (i.e., a second material) at a second depth D2 that is less than the first depth D1 during a subsequently performed CMP process (e.g., a first CMP process). In some examples, the enhancer may accomplish this by changing chemical and/or physical properties of a surface portion of the material B, rendering it more susceptible to the penetration of the abrasive 152. In some embodiments, the first depth D1 may be substantially zero (i.e., no penetration into the material A). In this regard, the enhancer in its active state CR′ functions to increase the RR of the material B relative to the material A, whose RR remains substantially constant.

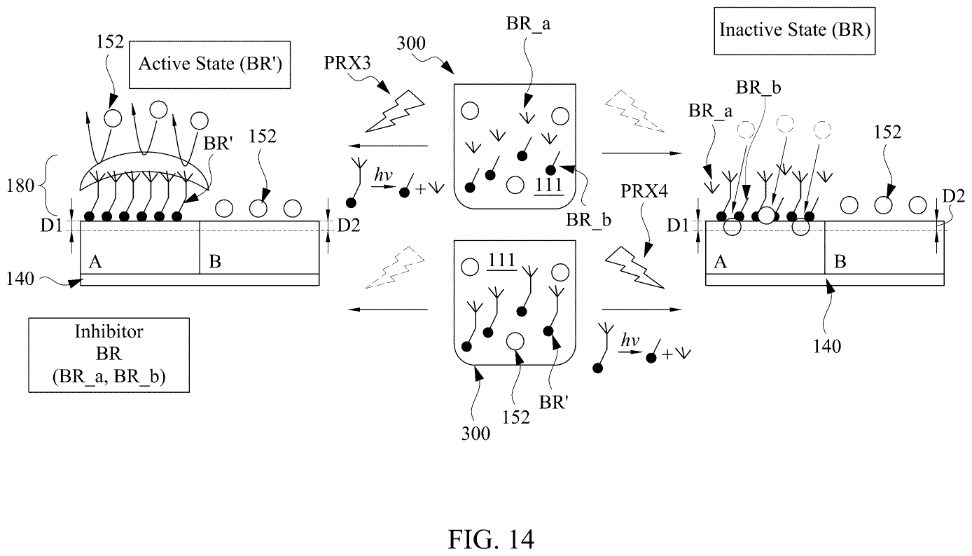

FIG. 14 illustrates a first photoreaction PRX3 that transforms the inhibitor (i.e., the additive 156) from an inactive state BR, at which the inhibitor includes a first component BR_a and a second component BR_b, to an active state BR′ (i.e., the first state). In the active state BR, the components BR_a and BR_b of the inhibitor polymerize in the first processed slurry mixture 111a to selectively form a protective layer 180 over the material A (i.e., the second material) relative to the material B (i.e., the first material), thereby limiting penetration of the abrasive 152 into the material A during the subsequently applied CMP process (e.g., the first CMP process). In other words, the inhibitor in its active state BR′ functions to reduce the RR of the material A relative to the material B, whose RR remains substantially constant. As depicted herein, the abrasive 152 may penetrate the material A at the first depth D1 and penetrate the material B at the second depth D2, where the depths D1 and D2 are substantially similar to or the same as one another. In some embodiments, the depths D1 and D2 may be substantially zero (i.e., no penetration into either the material A or the material B).

In an example embodiment, the enhancer and the inhibitor may each include a material with a chemical composition that comprises a disulfide functional group (R—S—S—R′), where R and R′ may each be a hydrogen (H) atom, a hydrocarbon side chain of any length, other suitable groups of atoms, or combinations thereof. In this regard, the —S—S— bond in the disulfide functional group may react to free radicals formed by light emitted from the light source of the light flow cell 300, leading to chemical transformation (e.g., activation of the enhancer or the inhibitor) described herein. In some examples, the light may be configured to have a wavelength in the UV spectrum. For embodiments in which the enhancer and/or the inhibitor are not photosensitive, the photosensitive reactor 170 may include acetone, propanol, other suitable photosensitive materials, or combinations thereof, which can produce free radicals when irradiated with UV light.

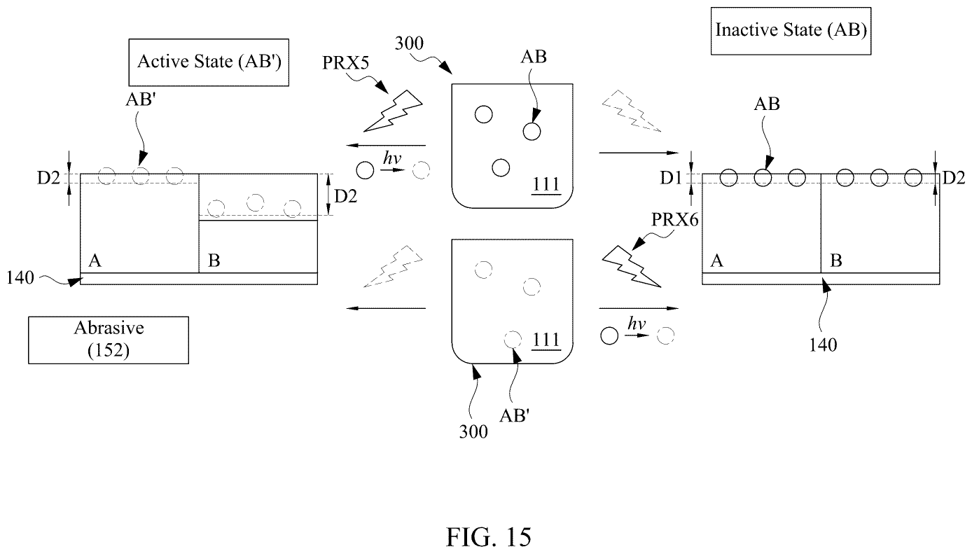

FIG. 15 illustrates a first photoreaction PRX5 that transforms the abrasive 152 from an inactive state AB to an active state AB′ (i.e., the first state). Similar to the effect of the enhancer in the active state CR′, in the active state AB′, the abrasive 152 in the first processed slurry mixture 111a penetrates the material B (i.e., a first material) at the first depth D1 and the material A (i.e., a second material) at the second depth D2 that is less than the first depth D1 during a subsequently performed CMP process (e.g., the first CMP process). In this regard, the abrasive 152 in its active state AB functions to increase the removal rate RR of the material B relative to the material A, whose RR remains substantially constant.

Referring to FIGS. 2-4, for example, the method 400 proceeds to operation 410 during which the first processed slurry mixture 111a is dispensed onto the platen 102.

Referring to FIGS. 1, 2, and 12C, for example, the method 400 proceeds to operation 412 during which the first CMP process is performed on the semiconductor wafer 140 using the first processed slurry mixture 111a. In some embodiments, the additive 156 in the first state (i.e., the processed additive 156′) causes the first CMP process to remove the first material at a first RR, as described in detail above with reference to FIGS. 13-15.

Referring to FIG. 12C, the (e.g., first) CMP process may be implemented as the method 450, may begins with operation 452 during which an upward suction force (using the vacuum implement described herein) is applied to retain the semiconductor wafer 140 inside the wafer carrier 106. The CMP process may proceed to operation 454 during which the platen 102 (and thus the polishing pad 104) is rotated at a suitable direction and rotational speed. The CMP process may proceed to operation 456 during which the slurry mixture 111 (e.g., the first processed slurry mixture 111a) is received and subsequently dispensed, after undergoing the photoreaction implemented by the light flow cell 300, onto the polishing surface 104s through the slurry delivery system 200. The CMP process may proceed to operation 458 during which the wafer carrier 106 is rotated, while being lowered, toward the polishing pad 104. When the rotation of the wafer carrier 106 reaches a desirable wafer-polishing speed, the CMP process proceeds to operation 460 during which a downward force (by pressing in a direction perpendicular to the polishing surface 104s, for example) is applied on the semiconductor wafer 140, causing it to engage (e.g., make direct contact with) the polishing surface 104s.

Thereafter, the method 450 may proceed to repeating the operations 454-460 during which the platen 102 is continuously rotated, the slurry mixture 111 (or the first processed slurry mixture 111a) is dispensed, the wafer carrier 106 is rotated, and the downward force on the semiconductor wafer 140 is applied, thereby causing the semiconductor wafer 140 to be gradually planarized. It is understood that additional steps/operations may be provided before, during, and after the method 450 of FIG. 12C.

By dispensing the first processed slurry mixture 111a that includes the additive 156 in the first state, the RR of one of the materials provided on the semiconductor wafer 140 (e.g., the first material or the second material) may be altered without requiring any substantial changes to made to a composition of the as-received slurry mixture 111, the polishing pad 104 (and/or the platen 102), or both. In some examples, two or more of the operations 408-412 may be implemented concurrently.

Subsequently, the method 400 proceeds to operation 414 during which at least one parameter of the first photoreaction (e.g., the first photoreactions PRX1, PRX3, or PRX5) is adjusted. In some embodiments, referring to FIGS. 7-11, adjusting the parameter includes adjusting at least one of a power of the light source of the light flow cell 300 (e.g., the light sources S1-S5), a number of the light elements (e.g., the LEDs in the arrays 341 or the array 351, the lamps 362 and 364 in the array 361, the lasers 372-376 in the array 371, or the lasers 382-386 in the array 381) included in the light source, an area irradiated by the light source, or a flow rate of the slurry mixture 111 (e.g., the first processed slurry mixture 111a), which includes the photosensitive agent PA (e.g., the photosensitive enhancer, the photosensitive inhibitor, the photosensitive abrasive, and/or the photosensitive reactor) flowing through the slurry conduit 202 of the slurry delivery system 200.

In some embodiments, adjusting the parameter of the first photoreaction generally results in an adjustment in a light efficiency (LE) of the light source. In the present disclosure, the LE is defined as a normalized percentage of the power (or intensity) of the light source capable of inducing a photoreaction of a given material to its fullest extent to transform the photosensitive agent PA to its active or inactive state. For example, a LE of 100% corresponds to the photosensitive agent PA being in a fully active state (i.e., a fully turned-on state) and a LE of 0% corresponds to the photosensitive agent PA being in a fully inactive state (i.e., a fully turned-off state). In some embodiments, the LE may be adjusted to a value between 0% and 100% to allow the photosensitive agent PA to be activated (or turned on) or deactivated (or turned off) to varying degrees. Advantageously, such adjustment of the extent of the photosensitive agent PA's reactivity allows the RRs of different materials to be adjusted to desired levels, thereby improving the uniformity of the polishing process.

For embodiments in which the enhancer is transformed to the active state CR′ by a photoreaction described herein, an increase in LE increases the RR of a given material, while a decrease in LE decreases the RR of the given material. For example, the RR is maximized when LE is at 100% and minimized when LE is at 0%. Conversely, if the enhancer is transformed to the inactive state CR by a photoreaction described herein, an increase in LE decreases the RR of a given material, while a decrease in LE increases the RR of the given material. For example, the RR is maximized when LE is at 0% and minimized when LE is at 100%.

For embodiments in which the inhibitor is transformed to the active state BR′ by a photoreaction described herein, an increase in LE decreases the RR of a given material, while a decrease in LE increases the RR of the given material. For example, the RR is maximized when LE is at 0% and minimized when LE is at 100%. Conversely, if the inhibitor is transformed to the inactive state CR by a photoreaction described herein, an increase in LE increases the RR of a given material, while a decrease in LE decreases the RR of the given material. For example, the RR is maximized when LE is at 100% and minimized when LE is at 0%.

Adjusting the LE may be accomplished by adjusting the extent of the exposure of the slurry mixture 111 to the light irradiated by light source during the first photoreaction, adjusting the amount of the photosensitive agent PA configured to react with the light by changing the flow rate of the slurry mixture 111, or both. For example, adjusting one or more of the power of the light source, the number of the light elements, or the area irradiated by the light can change the extent of the exposure of the slurry mixture 111 to the light. In some embodiments, the area irradiated by the light is adjusted by sliding the light mask (e.g., the light masks 348, 358, 368, 378, or 388), which causes the irradiation length (e.g., the irradiation lengths L1-L5) to change. In some examples, increasing the irradiation length leads to an increase in the area irradiated by the light.

Subsequently, the method 400 proceeds to operation 416 during which the light source S1-S5 is activated using the adjusted photoreaction parameter to initiate a second photoreaction. The second photoreaction transforms the additive 156 and/or the abrasive 152 from the first state to a second state, thereby resulting in a second processed slurry mixture 111b. In some examples, the operation 416 may be implemented concurrently with the operation 414. Alternatively, the operation 416 may be implemented after implementing the operation 414. Example transformations of the additive 156 and the abrasive 152 are schematically illustrated in FIGS. 13-15 and described in detail below.

FIG. 13 illustrates a second photoreaction PRX2 that transforms the enhancer (i.e., the additive 156) from an active state CR′ (i.e., the first state) to an active state CR (i.e., the second state). In the inactive state CR, the enhancer does not cause substantial change in the chemical and/or physical properties of the surface portion of the material B, reducing or minimizing the penetration of the abrasive 152 into the material B during the subsequently applied CMP process (e.g., a second CMP process). In some embodiments, the second depth D2 is substantially similar to or the same as the depth D1. In this regard, the enhancer in its inactive state CR functions to decrease the RR of the material B relative to the material A, whose RR remains substantially constant. In some embodiments, the depths D1 and D2 may be substantially zero (i.e., no penetration into either the material A or the material B).

FIG. 14 illustrates a second photoreaction PRX4 that transforms the inhibitor (i.e., the additive 156) from an active state BR′ (i.e., the first state) to an inactive state BR (i.e., the second state). In the inactive state BR, the inhibitor breaks down into the components BR_a and BR_b by the second photoreaction PRX4, thereby preventing or otherwise inhibiting the formation of the protective layer 180 over the material A. Such inhibition allows the abrasive 152 to penetrate the surface of the material A during the subsequently applied CMP process (e.g., the second CMP process), resulting in the first depth D1 into the material A to be greater than the second depth D2 into the material B. In some embodiments, the second depth D2 may be substantially zero (i.e., no penetration into the material B). In this regard, the inhibitor in its inactive state CR functions to increase the RR of the material A relative to the material B, whose RR remains substantially constant.

FIG. 15 illustrates a second photoreaction PRX6 that transforms the abrasive 152 from an active state AB′ (i.e., the first state) to an inactive state AB (i.e., the second state). Similar to the effect of enhancer in the inactive state CR, in the inactive state AB, the penetration of the abrasive 152 into the material B is reduced or minimized during the subsequently applied CMP process (e.g., the second CMP process). In some embodiments, the second depth D2 into the material B is substantially similar to or the same as the first depth D1 into the material A. In this regard, the abrasive 152 in its inactive state AB functions to decrease the RR of the material B relative to the material A, whose RR remains substantially constant. In some embodiments, the depths D1 and D2 may be substantially zero (i.e., no penetration into either the material A or the material B).

Referring to FIGS. 2-4, for example, the method 400 proceeds to operation 418 during which the second processed slurry mixture 111b is dispensed onto the platen 102.

Referring to FIGS. 1 and 2, for example, the method 400 proceeds to operation 420 during which the second CMP process is performed on the semiconductor wafer 140 using the second processed slurry mixture 111b. In some embodiments, the additive in the second state causes the second CMP process to remove the first material at a second RR that is different from the first RR, as described in detail above with reference to FIGS. 13-15. In some examples, two or more of the operations 414-420 may be implemented concurrently.

In some embodiments, the method 400 further proceeds to operation 422 during which additional processes are performed. In some examples, the operations 414-420 may optionally be repeated to polish any additional material, e.g., a material C, provided on the semiconductor wafer 140. In some examples, a cleaning process may be performed to remove any polishing residues produced during the first CMP process and the second CMP process.

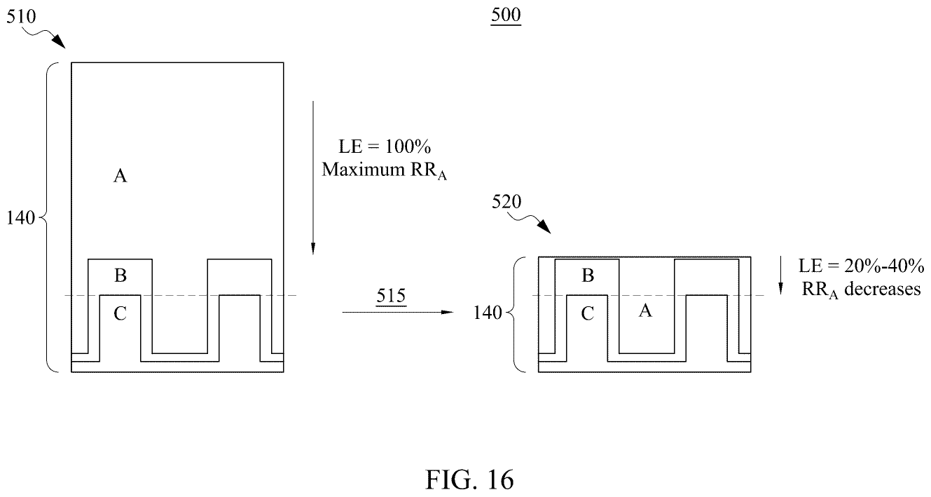

Example embodiments of a multi-step CMP process corresponding to operations of the method 400 are described in detail below with reference to FIGS. 16-21. It is understood that the numeric values of LE described herein are for illustrative purposes only and are not therefore intended to limit the embodiments of the present disclosure.

FIG. 16 depicts an example multi-step CMP process 500 aimed to planarizing the semiconductor wafer 140 that includes three materials, materials A, B, and C. The multi-step CMP process 500 includes step 510 that corresponds to the implementation of the first CMP process of the operation 412 after activating the light source of the light flow cell 300 to initiate the first photoreaction in the slurry mixture 111 (not depicted) at the operation 408, and dispensing the first processed slurry mixture 111a (not depicted) at the operation 410. Specifically, when using an enhancer (not depicted) capable of improving the polishing of the material A after being transformed to the active state CR′ by the photoreaction, the RR of the material A (RR_{A}) is tuned to a maximum value as the light source is implemented at an LE of approximately 100%. This allows the material A to be removed quickly and effectively in a high throughput setting without excessively removing the materials B and C. The process of transforming the enhancer to the active state CR′ is described in detail above with reference to the FIG. 13.

Subsequently, as indicated by step 515, at least one parameter of the first photoreaction is adjusted, followed by step 520 that includes the activation of the light source to initiate the second photoreaction, the dispensing of the second processed slurry mixture 111b (not depicted), and the implementation of the second CMP process, corresponding to the operations 414, 416, 418, and 420, respectively. In the depicted example, at least one parameter of the first photoreaction is adjusted to reduce the LE, thereby lowering the RR_{A} without substantially changing the RR of each of the materials B (RR_{B}) and C (RR_{C}).

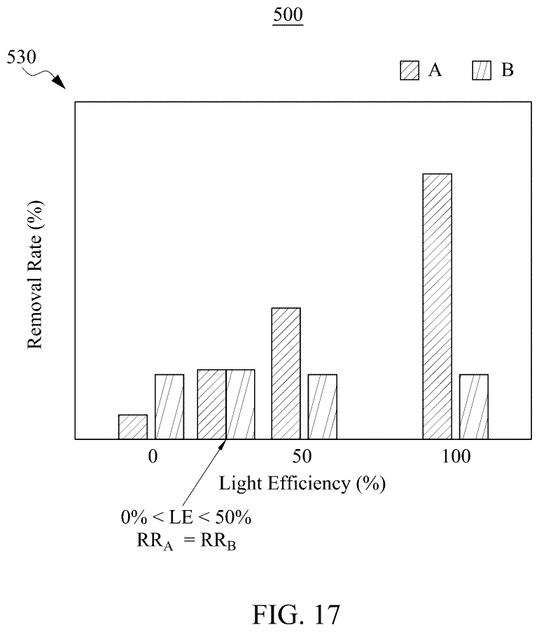

FIG. 17 illustrates a chart 530 describing changes in the RR in response to changes in the LE for the enhancer described in FIG. 16. As depicted, the RR_{A} increases with an increase in the LE, while the RR_{B} remains substantially the same as the LE changes from 0% to 100%. In some embodiments, adjusting the parameter of the photoreaction includes adjusting the LE to a value such that the resulting RR_{A} is substantially the same as, or matched to, the RR_{B}. This ensures that the two different materials are polished uniformly without requiring any substantial changes made to the CMP process and the apparatus (e.g., the apparatus 100) by which the CMP process is implemented. For example, reducing the LE from 100% to a value between 0% and 50%, e.g., between 20% and 40%, as indicated in FIG. 17, lowers the RR_{A} to a value substantially the same as the RR_{B}.

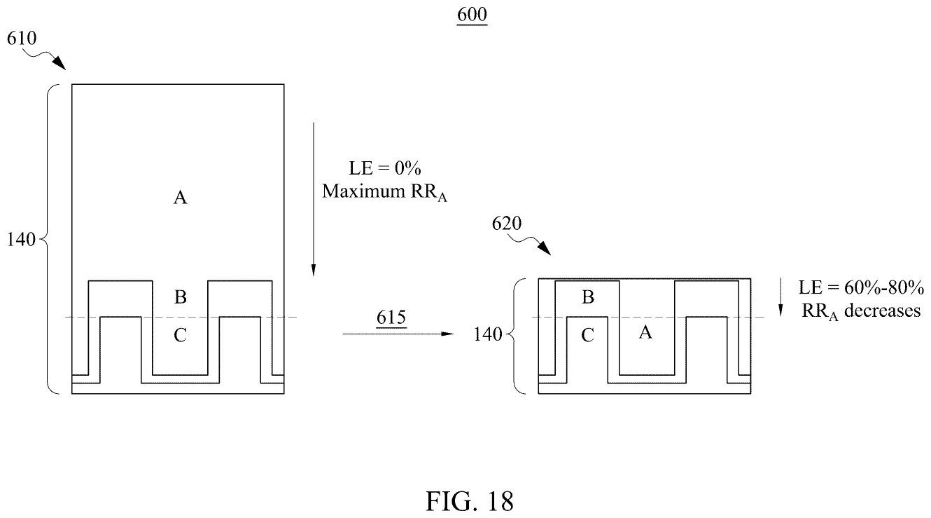

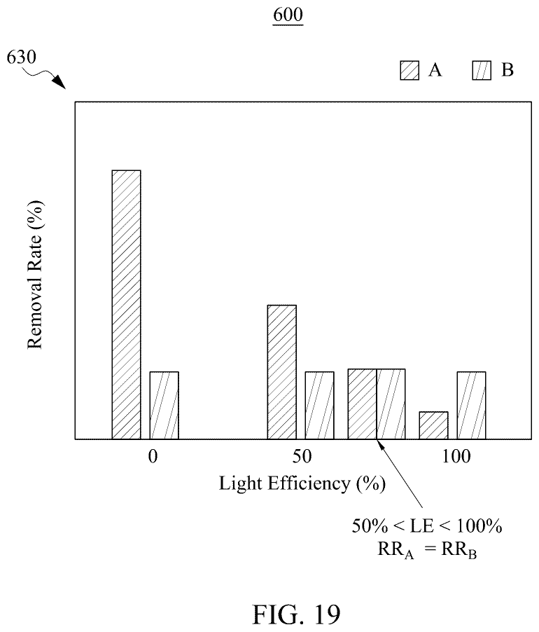

FIGS. 18 and 19 collectively depict an example multi-step CMP process 600 similar to the multi-step CMP process 500 of FIGS. 16 and 17. For example, referring to FIG. 18, step 610 corresponds to the implementation of the operations 408, 410, and 412 in a manner similar to that of the step 510. However, different from the step 510, when using an inhibitor (not depicted) capable of limiting the polishing of the material A after being activated (i.e., transformed to the active state BR′) by the photoreaction during the step 610, the RR_{A} is tuned to a maximum value as the light source is implemented at an LE of 0%. This allows the material A to be removed in a high throughput setting without excessively impacting the removal of the materials B and C. The process of transforming the inhibitor through the first photoreaction process is described in detail above with reference to FIG. 14.

Subsequently, as indicated by step 615, at least one parameter of the first photoreaction is adjusted, followed by step 620 that is similar to the step 520 described herein. In the depicted example, at least one parameter of the first photoreaction is adjusted to increase the LE, thereby lowering the RR_{A} without substantially changing the RR_{B} and the RR_{C}.

FIG. 19 illustrates a chart 630 describing changes in the RR in response to changes in the LE for the enhancer described in FIG. 18. As depicted, the RR_{A} decreases with an increase in the LE, while the RR_{B} remains substantially the same as the LE changes from 0% to 100%. In this regard, increasing the LE from 0% to a value between 50% and 100%, e.g., between 60% and 80%, as indicated in FIG. 19, lowers the RR_{A} to a value approximately the same as the RR_{B}.

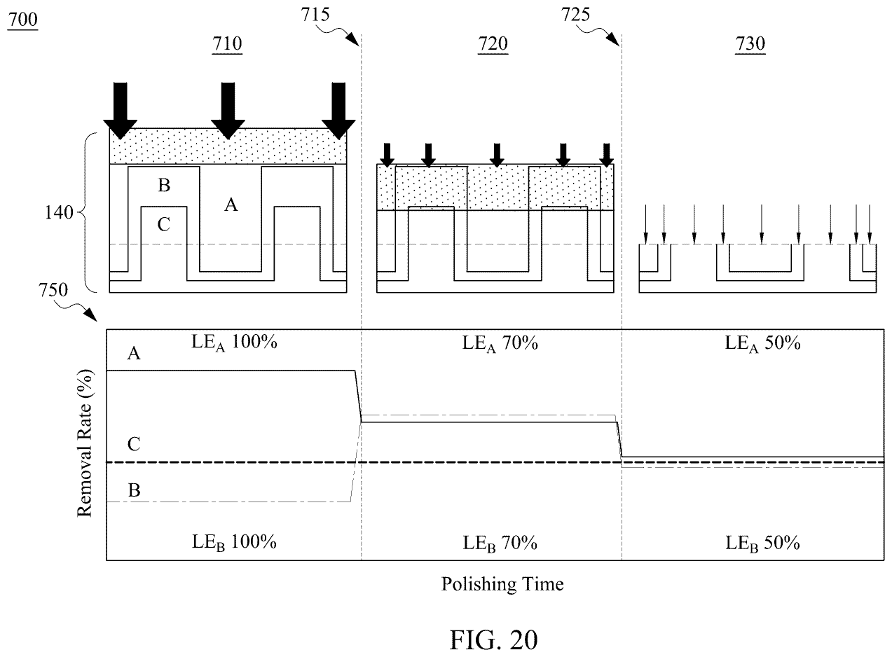

FIG. 20 illustrates an example multi-step CMP process 700 during which the RR_{A} and the RR_{B} are both varied, though to different extents and by different mechanisms, while the RR_{C} remains substantially unchanged at a non-zero value. The multi-step CMP process 700 includes at least steps 710, 715, 720, 725, and 730. In this example, a multi-wavelength light source, such as the light source S1-S5 described herein, may be utilized to control the activation or deactivation of the enhancers and/or inhibitors for the materials A and B, thereby allowing the RR_{A} and the RR_{B}, which correspond to polishing selectivity of the materials A and B, respectively, to be tuned independently. Furthermore, by adjusting the RR_{A} and the RR_{B} independently, the RRs (i.e., the polishing selectivity) of all three materials A, B, and C can be matched (e.g., matched to the RR_{C}) to obtain polishing uniformity across a top surface of the semiconductor wafer 140 without significantly impacting the throughput of the multi-step CMP process.

Specifically, the step 710 corresponds to the implementation of the operations 408, 410, and 412 in a manner similar to that of the step 510, where an enhancer for polishing the material A is activated by light having a wavelength λ_{A} such that at a LE_{A} of 100%, the RR_{A} is maximized. Concurrently during the step 710, an inhibitor for polishing the material B is activated by light having a wavelength λ_{B} such that at a LE_{B} of 100%, the RR_{B} is minimized. This allows the material A to be removed quickly and effectively in a high throughput setting without excessively removing the materials B and C. In some embodiments, the light having the wavelength λ_{A} and the light having the wavelength λ_{B} may be respectively irradiated by light elements arranged in an array of light elements, such as the light elements included in the arrays 341, 351, 361, 371, and 381.

Subsequently, as indicated by the step 715, at least one parameter of the first photoreaction is adjusted, followed by the step 720 that is similar to the step 520 described herein. In the depicted example, at least one parameter of the first photoreaction is adjusted to decrease both the LE_{A} and the LE_{B} for the second photoreaction, such as to 70% and 20%, respectively, thereby reducing the RR_{A} and increasing the RR_{B} concurrently without substantially changing the RR_{C} during the second CMP process. In some embodiments, the LE_{A} and the LE_{B} may be independently adjusted such that the RR_{A} is tuned to substantially the same value as the RR_{B}, which is greater than the RR_{C}. In this regard, the materials A and B may be polished uniformly without substantially impacting the removal of the material C.

Thereafter, as indicated by the step 725, at least one parameter of the second photoreaction is adjusted, followed by the step 730, which aims to remove all three materials at substantially the same RRs. Specifically, at least one parameter of the second photoreaction is adjusted to decrease the LE_{A} to 50% and increase the LE_{B} to 50% concurrently, thereby reducing both the RR_{A} and the RR_{B} to be substantially the same as the RR_{C}. In this regard, the materials A, B, and C may be polished uniformly without excessively removing any one of the materials.

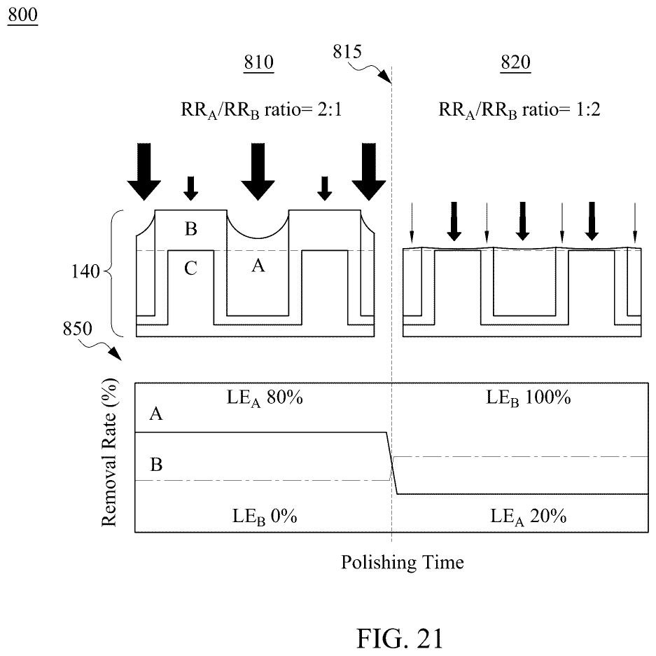

In addition to matching the RRs (i.e., the polishing selectivity) of the different materials, the RRs may also be reversed in some instances to achieve certain polishing results. For example, referring to FIG. 21, which illustrates an example multi-step CMP process 800 during which the RR_{A} and the RR_{B} are reversed. The multi-step CMP process 800 includes at least steps 810, 815, and 820, and may be implemented using a multi-wavelength light source to control the activation or deactivation of the enhancers and/or inhibitors for the materials A and B independently, in a manner similar to the multi-step CMP process 700.

Specifically, the step 810 corresponds to the implementation of the operations 408, 410, and 412 in a manner similar to that of the step 510, where an enhancer for polishing the material A is activated by light having a wavelength λ_{A} and implemented at a LE_{A} of 80%, and an enhancer for polishing the material B is deactivated by light having a wavelength λ_{B} and implemented at a LE_{B} of 0%. The resulting RR_{B} is therefore less than the resulting RR_{A} such that the ratio of the RR_{A} to the RR_{B} is greater than one (e.g., RR_{A}/RR_{B}=2:1). This allows the material A to be removed effectively in a higher throughput setting without excessively removing the material B.

Subsequently, as indicated by the step 815, at least one parameter of the first photoreaction is adjusted, followed by the step 820 that is similar to the step 520 described herein. In the depicted example, at least one parameter of the first photoreaction is adjusted to decrease the LE_{A} to 20% and increase the LE_{B} to 100%, thereby reducing the RR_{A} and increasing the RR_{B} concurrently. In this regard, the ratio of the RR_{A} to the RR_{B} is reversed (e.g., RR_{A}/RR_{B}=1:2). In the depicted embodiment, at the step 810, the relatively higher RR_{A} causes a dishing profile (i.e., having a concave surface) in the polished surface of the material A. By reversing the ratio of the RR_{A} to the RR_{B} using the multi-step CMP process 800 described herein, the dishing profile may be substantially corrected (or flattened) to achieve a more uniform polished surface on the semiconductor wafer 140.

In one aspect of the present disclosure, a chemical mechanical polishing (CMP) apparatus is provided. The CMP apparatus includes a platen and a wafer carrier disposed over the platen. The CMP apparatus further includes a slurry delivery system. The slurry delivery system includes a slurry conduit configured to dispense a slurry mixture onto the platen. The slurry delivery system further includes a light flow cell coupled to and circumferentially surrounding a segment of the slurry conduit, where the segment extends along a longitudinal axis. The light flow cell includes a light source configured to irradiate at least a portion of the segment.

In another aspect of the present disclosure, a CMP apparatus is provided. The CMP apparatus includes a platen. The CMP apparatus includes a slurry conduit configured to dispense a slurry mixture onto the platen. The CMP apparatus further includes a light flow cell coupled to and circumferentially surrounding a first segment of the slurry conduit that extends along a longitudinal axis. The light flow cell includes a light holder. The light flow cell includes a light source supported by the light holder and configured to irradiate at least a portion of the first segment. The light flow cell further includes a light mask removably positioned over the light source.

In yet another aspect of the present disclosure, a method of performing a CMP process is provided. The method includes providing a CMP apparatus including a platen, a wafer carrier, a slurry delivery system including a slurry conduit, and a light flow cell coupled to a segment of the slurry conduit, where the light flow cell including a light source. The method includes receiving a semiconductor wafer in the wafer carrier, where the semiconductor wafer includes a first material and a second material different from the first material in composition. The method includes receiving a slurry mixture in the slurry delivery system, where the slurry mixture includes an abrasive and an additive. The method includes activating the light source to initiate a first photoreaction that transforms the additive to a first state, thereby resulting in a first processed slurry mixture. The method includes dispensing the first processed slurry mixture onto the platen. The method further includes performing a first CMP process on the semiconductor wafer using the first processed slurry mixture, where the additive in the first state causes the first CMP process to remove the first material at a first removal rate.
As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chemical mechanical polishing (CMP) apparatus, comprising:
a platen;
a wafer carrier disposed over the platen;
a slurry delivery system, including:
a slurry conduit configured to dispense a slurry mixture onto the platen, and
a light flow cell coupled to and circumferentially surrounding a segment of the slurry conduit, the segment extending along a longitudinal axis, wherein the light flow cell includes a light source configured to irradiate at least a portion of the segment.

2. The CMP apparatus of claim 1, wherein the light flow cell further includes:
a light holder configured to positionally support the light source, and
a light mask positioned over the light source and slidable along the longitudinal axis to expose at least the portion of the segment to the light source.

3. The CMP apparatus of claim 2, wherein:
the light holder is configured as a first sheet,
the light source is disposed on a surface of the first sheet,
the light mask is configured as a second sheet extending over the light source, and
the segment is arranged in a serpentine pattern that extends across a surface of the second sheet.

4. The CMP apparatus of claim 2, wherein:
the light holder is configured as a first tube having a first lumen defined by a first tube body,
the light source extends through the first lumen along the longitudinal axis,
the light mask is configured as a second tube having a second lumen defined by a second tube body, the light holder extending through the second lumen along the longitudinal axis, and
the segment wraps around an outer surface of the second tube body in a helical pattern.

5. The CMP apparatus of claim 1, wherein the light source includes:
a first light element irradiating light having a first wavelength, and
a second light element irradiating light having a second wavelength that is different from the first wavelength.

6. The CMP apparatus of claim 1, wherein:
the slurry conduit includes an inlet and an outlet opposite the inlet,
the light flow cell is interposed between the inlet and the outlet along the longitudinal axis, and
the slurry delivery system further includes a slurry mixer fluidly coupled to the slurry conduit, the slurry mixer being interposed between the inlet and the light flow cell along the longitudinal axis or between the light flow cell and the outlet along the longitudinal axis.

7. The CMP apparatus of claim 1, wherein
the light source is positioned over and separated from the segment, and
the light flow cell further includes a light mask disposed between the segment and the light source, the light mask being slidable along the longitudinal axis to expose at least the portion of the segment to the light source.

8. A chemical mechanical polishing (CMP) apparatus, comprising:
a platen;
a slurry conduit configured to dispense a slurry mixture onto the platen; and
a light flow cell coupled to and circumferentially surrounding a first segment of the slurry conduit that extends along a longitudinal axis, the light flow cell including:
a light holder,
a light source supported by the light holder and configured to irradiate at least a portion of the first segment, and
a light mask removably positioned over the light source.

9. The CMP apparatus of claim 8, wherein:
the slurry conduit further includes a second segment and a third segment,
the first segment is fluidly coupled to each of the second segment and the third segment, and
the first segment includes a first segment body, the first segment body being optically transparent to the light source.

10. The CMP apparatus of claim 8, wherein the light source includes at least one of a light-emitting diode (LED), a lamp, or a laser.

11. The CMP apparatus of claim 10, wherein the light source includes an array of LEDs, the LEDs having a first subset arranged along the longitudinal axis and a second subset arranged circumferentially along an outer surface of the light holder, wherein the first subset are configured to emit light in the same wavelength and the second subset are configured to emit light in different wavelengths.

12. A method of performing a chemical mechanical polishing (CMP) process, comprising:
providing a CMP apparatus including a platen, a wafer carrier, a slurry delivery system including a slurry conduit, and a light flow cell coupled to a segment of the slurry conduit, the light flow cell including a light source;
receiving a semiconductor wafer in the wafer carrier, the semiconductor wafer including a first material and a second material different from the first material in composition;
receiving a slurry mixture in the slurry delivery system, the slurry mixture including an abrasive and an additive;
activating the light source to initiate a first photoreaction that transforms the additive to a first state, thereby resulting in a first processed slurry mixture;
dispensing the first processed slurry mixture onto the platen; and
performing a first CMP process on the semiconductor wafer using the first processed slurry mixture, the additive in the first state causing the first CMP process to remove the first material at a first removal rate.

13. The method of claim 12, wherein the additive includes at least one of a photosensitive polishing enhancer or a photosensitive polishing inhibitor, and wherein the first photoreaction directly transforms the additive to the first state.

14. The method of claim 12, wherein:
the slurry mixture further includes a photosensitive reactor,
the additive includes at least one of a polishing enhancer or a polishing inhibitor, and
the first photoreaction transforms the photosensitive reactor into an activated photosensitive reactor that subsequently transforms the additive to the first state.

15. The method of claim 12, wherein the first state is an active state, and wherein the additive in the active state causes the abrasive to penetrate the first material at a first depth and the second material at a second depth that is less than the first depth.

16. The method of claim 12, wherein the first photoreaction transforms the abrasive to the first state.

17. The method of claim 12, further comprising:
subsequent to performing the first CMP process, adjusting a parameter of the first photoreaction;
activating the light source using the adjusted parameter to initiate a second photoreaction that transforms the additive to a second state, thereby resulting in a second processed slurry mixture;
dispensing the second processed slurry mixture onto the platen; and
performing a second CMP process on the semiconductor wafer using the second processed slurry mixture, the additive in the second state causing the second CMP process to remove the first material at a second removal rate, the second removal rate being different from the first removal rate.

18. The method of claim 17, wherein adjusting the parameter of the first photoreaction includes adjusting at least one of a power of the light source, a number of light elements included in the light source, an area irradiated by the light source, or a flow rate of the additive flowing through the slurry delivery system.

19. The method of claim 18, wherein the light source includes at least two light elements, and wherein adjusting the parameter of the first photoreaction includes adjusting the power of each of the light elements independently.

20. The method of claim 17, wherein each of the first CMP process and the second CMP process removes the second material relative to the first material at a third removal rate, and wherein adjusting the parameter of the first photoreaction causes the second removal rate to be the same as the third removal rate.
